(19) United States
(12) Patent Application Publication
(10) Pub. No.: US 2006/0124616 A1
(43) Pub. Date: Jun. 15, 2006

(54) Laser dicing apparatus for a silicon wafer and dicing method thereof

(76) Inventor: Chih-Ming Hsu, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/184,957

(22) Filed: Jul. 20, 2005

(30) Foreign Application Priority Data
Dec. 14, 2004 (TW) 093138745

(51) Int. Cl. B23K 26/38; H01L 21/78; H01L 21/301

(52) U.S. Cl. 219/121.67; 219/121.72; 438/463

(57) ABSTRACT

The present invention discloses a laser dicing apparatus for a silicon wafer and a dicing method thereof, wherein firstly, a silicon wafer, which has multiple chips with a scribed line drawn between every two chips, is provided; next, the silicon wafer is disposed on a working table having a vacuum device and fixed by the vacuum device; next, the working table and a laser are positioned by a control device; next, the laser is directed by a light-guide device to focus at one of the scribed lines; and lastly, the scribed lines on the silicon wafer are sequentially cut by the laser in order to dice the silicon wafer into multiple separate chips. The present invention can reduce the cutting harm on chips, lower the cost, accelerate the fabrication and improve environmental problems.

### BACKGROUND OF THE INVENTION

1. Field of the Invention

The present invention relates to a laser dicing apparatus for a silicon wafer and a dicing method thereof, particularly to a waterless laser dicing apparatus for a silicon wafer and a dicing method thereof.

2. Description of the Related Art

Wafer generally refers to a crystalline silicon plate, which is used to fabricate semiconductor integrated circuits; the reason why it is called wafer is that it is very circular. Silicon is the most common element in the earth crust, and the primary component of many kinds of rocks is exactly silicon dioxide. Silicon is extracted from silicon oxide in rocks via a reduction process, whereby a virgin polycrystalline silicon of about 98% purity can be obtained, and the virgin polycrystalline silicon is further purified and processed into a single-crystal silicon.

An integrated circuit combines many different semiconductor elements, such as transistors, diodes, resistors, capacitors, etc., in one silicon chip, and integrates the functions of those elements to perform logic functions. A silicon wafer has multiple chips or dice, and a silicon wafer will be separated into multiple chips or dice via a dicing process, and then, those separated chips will be further tested, packaged and so on before being delivered as finished products.

At present, silicon wafers are separated via a dicing blade; however, such a process is time- and material-consuming; further, it is a wet cutting, wherein water is used to reduce the heat created in cutting operation and to flush away the debris or the particles generated by cutting abrasion; thus, there is also a problem of processing waste water, and the cleanness of the product may not be so perfect as demanded.

Accordingly, the present invention proposes a laser dicing apparatus for a silicon wafer and a dicing method thereof in order to overcome the aforementioned problems.

### SUMMARY OF THE INVENTION

The primary objective of the present invention is to provide a laser dicing apparatus for a silicon wafer and a dicing method thereof, wherein a laser having a very small beam diameter is used to separate a silicon wafer so that the harm resulting from a separation process can be reduced and the fabrication cost can be lowered.

Another objective of the present invention is to provide a laser dicing apparatus for a silicon wafer and a dicing method thereof, which uses a laser to separate a silicon wafer in order to accelerate the fabrication process.

Further another objective of the present invention is to provide a laser dicing apparatus for a silicon wafer and a dicing method thereof, which uses a laser to separate a silicon wafer in order to avoid the debris or the waste water generated by the conventional cutting method so that the environmental problems can be improved and the product cleanness can be promoted.

To achieve the aforementioned objectives, the present invention proposes a laser dicing apparatus for a silicon wafer, which comprises: a working table, having a vacuum device to fix a silicon wafer, wherein the silicon wafer has multiple chips or dice with a scribed line drawn between every two chips; a laser, used to separate the silicon wafer into multiple chips or dice; a light-guide device, directing the laser to aim at the silicon wafer; and a control device, positioning the working table and the laser to enable the laser to focus at one of the scribed lines on the silicon wafer in order to dice the silicon wafer into multiple separate chips.

To achieve the aforementioned objectives, the present invention further proposes a laser dicing method for a silicon wafer, wherein firstly, a silicon wafer, which has multiple chips or dice, is provided; next, a scribed line is drawn between every two chips; next, the silicon wafer is disposed on a working table having a vacuum device and fixed by the vacuum device; next, the working table and a laser are positioned by a control device to enable the laser to aim at one of the scribed lines on the silicon wafer; next, the laser is directed by a light-guide device to focus at one of the scribed lines; and lastly, the scribed lines on the silicon wafer are sequentially cut by the laser in order to dice the silicon wafer into multiple separate chips.

To enable the objectives, technical contents, characteristics, and accomplishments of the present invention to be more easily understood, the embodiments of the present invention are to be described below in detail in cooperation with the attached drawings.

### BRIEF DESCRIPTION OF THE DRAWINGS

FIG. 1 is a schematic block diagram showing the laser dicing apparatus for a silicon wafer according to the present invention.

FIG. 2 a schematic enlarged view showing a scribed line and a cut channel generated by the laser dicing apparatus for a silicon wafer according to the present invention.

FIG. 3 is a flowchart of the laser dicing method for a silicon wafer according to the present invention.

### DETAILED DESCRIPTION OF THE INVENTION

In order to overcome the cost and the environmental problems of the conventional technology, wherein a dicing blade is used to cut a silicon wafer, which needs water to reduce heat and flush away debris, the present invention proposes a laser dicing apparatus for a silicon wafer and a dicing method thereof.

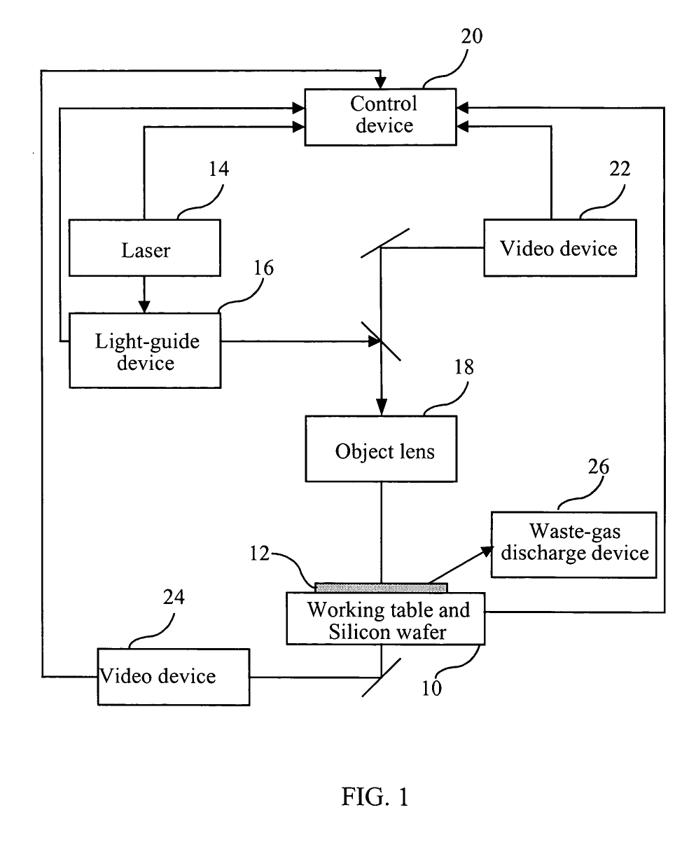

Refer to FIG. 1 a schematic block diagram showing the laser dicing apparatus for a silicon wafer according to the present invention. The laser dicing apparatus for a silicon wafer according to the present invention comprises: a working table 10, having a vacuum device to fix a silicon wafer 12 with a thickness ranging from 60 to 300 μm, wherein before being fixed to the working table 10, the silicon wafer 12 can be stuck onto a holding film beforehand for its planarity, and the silicon wafer 12 has multiple chips or dice with a scribed line drawn between every two chips; a laser 14, used to separate the silicon wafer 12 into multiple chips or dice; a light-guide device 16, coupled to the laser 14, and directing the laser 14 to aim at the silicon wafer 12, and adjusting the focal length from the laser 14 to the silicon wafer 12 via an object lens 18; and a control device 20 (such as a computer), positioning the working table 10 and the laser 14 and the light-guide device 16 to enable the laser 14 to focus at one of the scribed lines on the silicon wafer 12 in order to dice the silicon wafer 12 into multiple separate chips.

The laser dicing apparatus for a silicon wafer according to the present invention can further comprises: two video devices 22, 24, separately disposed above and below the working table 10, and used to observe whether the laser 14 has precisely focused at one of the scribed lines on the silicon wafer 12; and a waste-gas discharge device 26, disposed above the working table 10, and used to exhaust the waste gas and the particles generated when the laser 14 cuts the silicon wafer 12. Further, the waste-gas discharge device 26 can further has a particle-removing device for removing the particles and a gas-exhaust device for discharging waste gas.

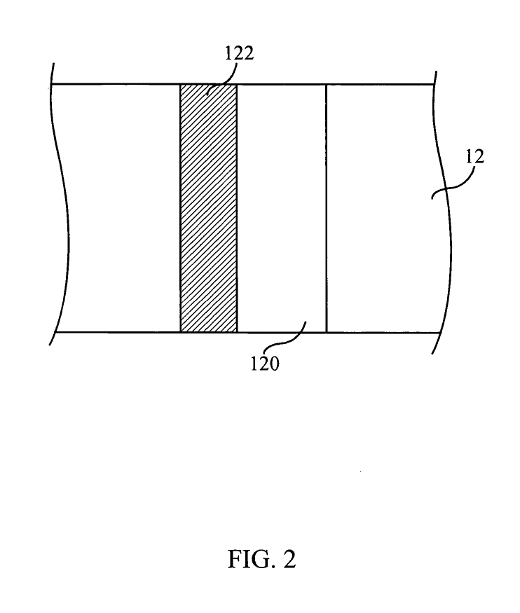

The parameters of the laser 14 include: a wavelength ranging from 200 to 750 nanometer, a frequency ranging from 20 to 80 KHz, an energy density ranging from 10 to 250 J/cm², an operation duration according to a cutting speed ranging from 10 to 40 mm/sec, and a light beam diameter ranging from 10 to 30 μm. As the diameter of the laser beam used in the present invention is pretty small, the width of the cut channel inside the scribed line is also smaller, which will harm the silicon wafer less. As shown in FIG. 2, when the laser 14 burns a cut channel 122 inside the scribed line 120 on the silicon wafer 12, the width of the cut channel 122 will not exceed that of the scribed line 120. Therefore, the laser dicing process will harm a silicon wafer less.

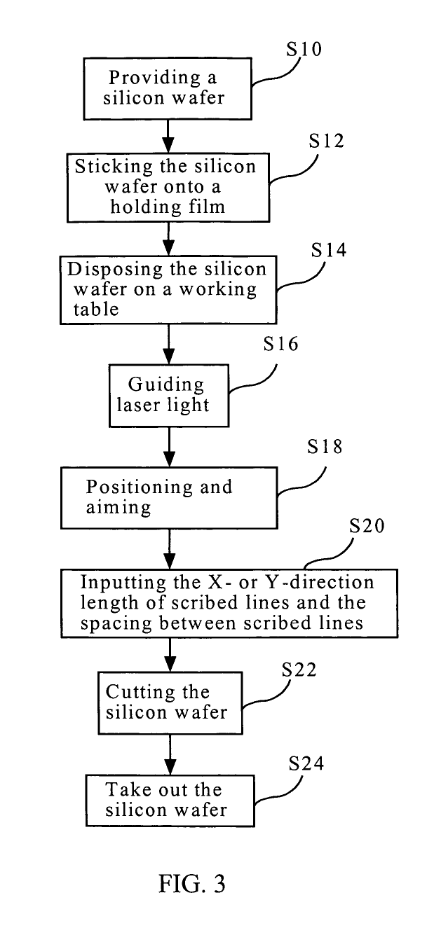

Refer to FIG. 3. The present invention further proposes a laser dicing method for a silicon wafer, comprising the following steps: firstly, providing a silicon wafer, which has multiple chips or dice with a scribed line drawn between every two chips (S10); next, sticking the silicon wafer onto a holding film for its planarity (S12); under a vacuum environment, such as in a clean room or a dustless room, disposing the silicon wafer together with the holding film on a working table having a vacuum device, and fixing them with the vacuum device (S14); next, utilizing a light-guide device to direct a laser to aim at the silicon wafer (S16); utilizing a control device to position the working table and the laser to enable the laser to focus at one of the scribed lines on the silicon wafer (S18), wherein the control device can control the working table to move along the X axis and Y axis of the silicon wafer and to rotate the silicon wafer, and an object lens can be used to adjust the focal length, i.e. the Z axis, and the distance between the object lens and the laser can be adjusted according to the thickness of the silicon wafer, and two video devices are used to observe whether the laser has precisely focused at one scribed line on the silicon wafer; next, inputting the moving speed of the working table and the laser parameters, such as wavelength, frequency, energy, and duration, and inputting the X- or Y-direction length of the scribed line aimed by the laser and the spacing between it and the scribed line to be cut next (S20); next, undertaking dicing to separate the silicon wafer into multiple chips or dice with the cut depth by which the laser cuts the scribed line being larger than one tenth of the silicon wafer's thickness, and utilizing a waste-gas discharge device to discharge the waste-gas and the particles generated in laser cutting (S22); and lastly, the working table automatically stopping moving once all the scribed lines have been cut, and shutting the vacuum device of the working table, and taking out the cut chips or dice to complete the dicing operation (S24).

The present invention proposes a laser dicing apparatus for a silicon wafer and a dicing method thereof, wherein not the conventional wet-cutting method but a laser dry-cutting method is adopted, and wherein a dicing blade or a large amount of water is no more needed and the debris is also lessened, and wherein the fabrication time is shortened; the cost is reduced; and the environmental problem is improved, and wherein a laser with a very small beam diameter is used to cut the silicon wafer, and thus, the width of the cut channel inside the scribed line is also smaller, and the harm on the silicon wafer is also minimized.

Those embodiments described above are only to clarify the present invention to enable the persons skilled in the art to understand, make, and use the present invention but not intended to limit the scope of the present invention. Any equivalent modification or variation without departing from the spirit of the present invention disclosed herein is to be included within the scope of the claims stated below.

What is claimed is:

1. A laser dicing apparatus for a silicon wafer, comprising:
a working table, having a vacuum device, wherein a silicon wafer is disposed on said working table, and said silicon wafer has multiple chips with a scribed line drawn between every two said chips, and said working table uses said vacuum device to fix said silicon wafer;
at least one laser, used to dice said silicon wafer into multiple separate said chips;
a light-guide device, coupled to said laser, and directing said laser to aim at said silicon wafer; and
a control device, used to position said working table, said laser, and said light-guide device to enable said laser to focus sequentially at said scribed lines of said silicon wafer in order to dice said silicon wafer into multiple separate said chips.

2. The laser dicing apparatus for a silicon wafer according to claim 1, further comprising at least one video device, which is coupled to said working table and said control device and used to observe whether said laser has aimed at one of said scribed lines on said silicon wafer.

3. The laser dicing apparatus for a silicon wafer according to claim 1, further comprising a waste-gas discharge device, which is disposed above said working table to discharge the waste gas and the particles generated in the laser dicing process.

4. The laser dicing apparatus for a silicon wafer according to claim 3, wherein said waste-gas discharge device further comprises a particle-removing device for removing said particles and a gas-exhausting device for discharging said waste gas.

5. The laser dicing apparatus for a silicon wafer according to claim 1, wherein said laser has a wavelength ranging from 200 to 570 nm.

6. The laser dicing apparatus for a silicon wafer according to claim 1, wherein said laser has a frequency ranging from 20 to 80 KHz.

7. The laser dicing apparatus for a silicon wafer according to claim 1, wherein said laser has an energy density ranging from 10 to 250 J/cm².

8. The laser dicing apparatus for a silicon wafer according to claim 1, wherein the operation duration of said “dice said silicon wafer into multiple separate said chips” according to a cutting speed ranging from 10 to 40 mm/sec.

9. The laser dicing apparatus for a silicon wafer according to claim 1, wherein said silicon wafer has a thickness ranging 60 to 300, m.

10. The laser dicing apparatus for a silicon wafer according to claim 1, wherein said control device is a computer.

11. A laser dicing method for a silicon wafer, comprising the following steps:
providing a silicon wafer, which has multiple chips with a scribed line drawn between every two said chips;
disposing said silicon wafer on a working table having a vacuum device, and fixing said silicon wafer with said vacuum device;
utilizing at least one control device to position said working table and at least one laser to enable said laser to focus at one of said scribed lines; and
utilizing said laser to sequentially cut said scribed lines in order to dice said silicon wafer into multiple separate said chips.

12. The laser dicing method for a silicon wafer according to claim 11, wherein said silicon wafer is stuck onto a holding film, and then, said silicon wafer together with said holding film is disposed on said working table.

13. The laser dicing method for a silicon wafer according to claim 11, wherein said silicon wafer is disposed on said working table under a vacuum environment.

14. The laser dicing method for a silicon wafer according to claim 11, wherein said control device can control said working table to move or rotate said silicon wafer.

15. The laser dicing method for a silicon wafer according to claim 11, wherein the moving speed of said working table and the laser parameters for cutting said scribed lines can be input into said control device.

16. The laser dicing method for a silicon wafer according to claim 11, further comprising a step of utilizing a light-guide device to direct said laser to aim at said silicon wafer before the step of said “utilizing at least one control device to position said working table and at least one laser”.

17. The laser dicing method for a silicon wafer according to claim 11, wherein during the step of said “utilizing at least one control device to position said working table and at least one laser to enable said laser to focus at one of said scribed lines”, an object lens is used to adjust a focal length for said laser's aiming at one of said scribed lines.

18. The laser dicing method for a silicon wafer according to claim 11, wherein during the step of said “utilizing at least one control device to position said working table and at least one laser to enable said laser to focus at one of said scribed lines”, said control device utilizes at least one video devices to observe whether said laser has precisely aimed at said scribed line.

19. The laser dicing method for a silicon wafer according to claim 11, wherein during the step of said “utilizing said laser to sequentially cut said scribed lines in order to dice said silicon wafer into multiple separate said chips”, a waste-gas discharge device is used to discharge the waste gas and the particles generated in the laser cutting process.

20. The laser dicing method for a silicon wafer according to claim 11, wherein the cut depth by which said laser cuts said scribed lines is larger than one tenth of said silicon wafer's thickness.
